(19) United States
(12) Patent Application Publication
(10) Pub. No.: US 2019/0035944 A1
(43) Pub. Date: Jan. 31, 2019

(54) SCHOTTKY DIODE

(71) Applicants: TOYOTA JIDOSHA KABUSHIKI KAISHA, Toyota-shi, Aichi-ken (JP); DENSO CORPORATION, Kariya-city, Aichi-pref. (JP)

(72) Inventors: Tatsuji NAGAOKA, Nagakute-shi (JP); Sachiko AOI, Nagakute-shi (JP); Yasushi URAKAMI, Kariya-shi (JP)

(73) Assignees: TOYOTA JIDOSHA KABUSHIKI KAISHA, Toyota-shi, Aichi-ken (JP); DENSO CORPORATION, Kariya-city, Aichi-pref. (JP)

(21) Appl. No.: 16/072,417

(22) PCT Filed: Jan. 31, 2017
(86) PCT No.: PCT/IB2017/000049

§ 371 Date: Jul. 24, 2018

(30) Foreign Application Priority Data
Feb. 2, 2016 (JP) 2016-018117

(51) Int. Cl. H01L 29/872; H01L 29/06

(52) U.S. Cl. CPC H01L 29/872; H01L 29/0649; H01L 29/0611

(57) ABSTRACT

A diode includes a semiconductor substrate; a top surface electrode in contact with a part of the top surface of the semiconductor substrate; and a bottom surface electrode in contact with at least a part of the bottom surface of the semiconductor substrate. The semiconductor substrate includes: an n-type high-concentration layer in ohmic contact with the bottom surface electrode; an n-type intermediate-concentration layer on a part of the n-type high-concentration layer; and an n-type low-concentration layer on a part of the n-type high-concentration layer. The n-type low-concentration layer surrounds the n-type intermediate-concentration layer. The top surface electrode is in Schottky contact with a top surface of the n-type intermediate-concentration layer, and a contact region where the top surface electrode and the semiconductor substrate are in contact extends onto then-type low-concentration layer beyond the n-type intermediate-concentration layer.

### BACKGROUND OF THE INVENTION

### 1. Field of the Invention

The invention relates to a diode.

### 2. Description of Related Art

Japanese Patent Application Publication No. 2013-102081 (JP 2013-102081 A) discloses an SBD (abbreviation of Schottky barrier diode) that includes an n-type semiconductor substrate, an anode electrode that is in contact with a part of a top surface of the semiconductor substrate, and a cathode electrode that is in contact with a bottom surface of the semiconductor substrate. In the semiconductor substrate, an n⁺ type semiconductor layer that is in ohmic contact with the cathode electrode and an n-type semiconductor layer that is formed on the n⁺ type semiconductor layer and in Schottky contact with the anode electrode are formed. It is also disclosed that a p-type semiconductor layer is formed in an area that is in contact with an end of the anode electrode. The p-type semiconductor layer is confined to the vicinity of the top surface of the n-type semiconductor layer and is separated from the n⁺ type semiconductor layer. The utilization of such a p-type semiconductor layer helps to alleviate concentration of electric field, which is prone to occur in the vicinity of an end of the anode electrode, to improve reverse voltage resistance.

### SUMMARY OF THE INVENTION

There are cases in the SBD of JP 2013-102081 A where a p-type semiconductor layer cannot be formed in an area that is in contact with an end of the anode electrode. For example, a p-type semiconductor layer may not be formed in an area that is in contact with an end of the anode electrode because of the restrictions relating to the arrangement of each region in the semiconductor substrate or the restrictions in the production process of the SBD. A possible solution in such a case is to form a low-concentration n-type semiconductor layer or to form an i-type semiconductor layer (in other words, a region to which no impurity is added intentionally) instead of a p-type semiconductor layer. An example of such an SBD is shown in FIG. 8. In an SBD 502 in FIG. 8, a low-concentration layer 534 as a low-concentration n-type semiconductor layer is provided instead of a p-type semiconductor layer. The SBD 502 has an n-type semiconductor substrate 504, an anode electrode 510, and a cathode electrode 520. The semiconductor substrate 504 has a high-concentration layer 530, an intermediate-concentration layer 532, and a low-concentration layer 534. The high-concentration layer 530, the intermediate-concentration layer 532 and the low-concentration layer 534 are all n-type semiconductor layers. The anode electrode 510 is in Schottky contact with a top surface of the intermediate-concentration layer 532.

When a reverse bias is applied between the anode electrode 510 and the cathode electrode 520 in the SBD 502 in FIG. 8, a depletion layer 590 that extends from a Schottky interface (in other words, the interface between the anode electrode 510 and the intermediate-concentration layer 532) into the semiconductor substrate 504 is formed. The depletion layer 590 is formed in the intermediate-concentration layer 532 and in the low-concentration layer 534. Because the low-concentration layer 534 has a lower n-type impurity concentration than the intermediate-concentration layer 532, the depletion layer 590 extends more easily in the low-concentration layer 534 than in the intermediate-concentration layer 532. In FIG. 8, equipotential lines that show the potential distribution in the depletion layer 590 are virtually illustrated (refer to the broken lines in the drawing). As shown in FIG. 8, the intervals between the equipotential lines in the low-concentration layer 534 are relatively larger than those in the intermediate-concentration layer 532. However, in the SBD 502 in FIG. 8, the low-concentration layer 534 is confined to the vicinity of the top surface of the intermediate-concentration layer 532 and is separated from the high-concentration layer 530. Thus, when the depletion layer 590 extends, a part in which the intervals between the equipotential lines are narrower than those in the low-concentration layer 534 is generated in the intermediate-concentration layer 532 under the low-concentration layer 534, resulting in a high electric field. Because this causes irregular changes in potential in the vicinity of an end of the anode electrode 510, concentration of electric field in the vicinity of the end of the anode electrode 510 is not sufficiently alleviated, making it impossible to provide the SBD with high voltage resistance.

The invention provides a technique by which high voltage resistance can be achieved without forming a p-type semiconductor layer in the vicinity of an end of the top surface electrode.

An aspect of the invention provides a diode. The diode according to the aspect includes a semiconductor substrate; a top surface electrode in contact with a part of the top surface of the semiconductor substrate; and a bottom surface electrode in contact with at least a part of the bottom surface of the semiconductor substrate. The semiconductor substrate includes: an n-type high-concentration layer in ohmic contact with the bottom surface electrode; an n-type intermediate-concentration layer on a part of the n-type high-concentration layer; and an n-type low-concentration layer on a part of the n-type high-concentration layer. The n-type intermediate-concentration layer has a lower n-type impurity concentration than the n-type high-concentration layer. The n-type low-concentration layer surrounds the n-type intermediate-concentration layer when the semiconductor substrate is viewed in a plan view. The n-type low-concentration layer has a lower n-type impurity concentration than the n-type intermediate-concentration layer. The top surface electrode is in Schottky contact with a top surface of the n-type intermediate-concentration layer, and a contact region where the top surface electrode and the semiconductor substrate are in contact extends onto the n-type low-concentration layer beyond the n-type intermediate-concentration layer. The n-type intermediate-concentration layer is an n-type semiconductor layer that is in Schottky contact with the top surface electrode. The low-concentration layer may be what is called an i-type semiconductor layer.

According to the above configuration, the n-type low-concentration layer is on a part of the n-type high-concentration layer and is not separated from the n-type high-concentration layer. In addition, the top surface electrode is in Schottky contact with a top surface of the n-type intermediate-concentration layer and extends onto the n-type low-concentration layer. These help to make the potential change in the vicinity of an end of the top surface electrode under a reverse bias less irregular. Thus, concentration of electric field in the vicinity of the end of the top surface electrode is sufficiently alleviated. As a result, high voltage resistance can be achieved without forming a p-type semiconductor layer in the vicinity of an end of the top surface electrode.

In the aspect of the invention, the diode may further include an insulating layer surrounding the n-type intermediate-concentration layer in the n-type low-concentration layer when the semiconductor substrate is viewed in a plan view. And an end of the contact region may be located on the insulating layer.

According to this configuration, the provision of the insulating layer helps to further alleviate concentration of electric field in the vicinity of an end of the top surface electrode.

In the aspect of the invention, the diode may further include a field plate electrode facing the n-type low-concentration layer via an interlayer insulating film. And the field plate electrode may be connected to the top surface electrode. And an end of the field plate electrode opposite the top surface electrode may be located in a direction to the top surface of the semiconductor substrate from the n-type low-concentration layer.

According to this configuration, because a field plate electrode is provided, a depletion layer extends to a position laterally away from an end of the top surface electrode when a reverse bias is applied. This helps to further alleviate concentration of electric field in the vicinity of an end of the top surface electrode. In addition, because the end of the field plate electrode opposite the top surface electrode is located on the n-type low-concentration layer, concentration of electric field in the vicinity of an end of the field plate electrode is also alleviated sufficiently.

In the aspect of the invention, the interlayer insulating film may have a dielectric constant higher than that of the n-type low-concentration layer.

In the aspect of the invention, the interlayer insulating film may have a dielectric constant higher than that of SiO₂.

According to this configuration, the intervals at which potentials are distributed (in other words, the intervals between equipotential line) in the depletion layer in the interlayer insulating film relatively increase. This sufficiently produces the effect of alleviating concentration of electric field in the vicinity of an end of the top surface electrode 10.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a cross-sectional view of an SBD 2 of a first embodiment;

FIG. 2 is a diagram illustrating the state of SBD 2 in FIG. 1 under a reverse bias;

FIG. 3 is a cross-sectional view of an SBD 102 of a second embodiment;

FIG. 4 is a diagram illustrating the state of the SBD 102 in FIG. 3 under a reverse bias;

FIG. 5 is a cross-sectional view of an SBD 202 of a third embodiment;

FIG. 6 is a diagram illustrating the state of the SBD 202 in FIG. 5 under a reverse bias.

FIG. 7 is a cross-sectional view of an SBD 302 of a fourth embodiment; and

FIG. 8 is a diagram illustrating the state of an SBD 502 of a comparative example under a reverse bias.

### DETAILED DESCRIPTION OF EMBODIMENTS

### First Embodiment

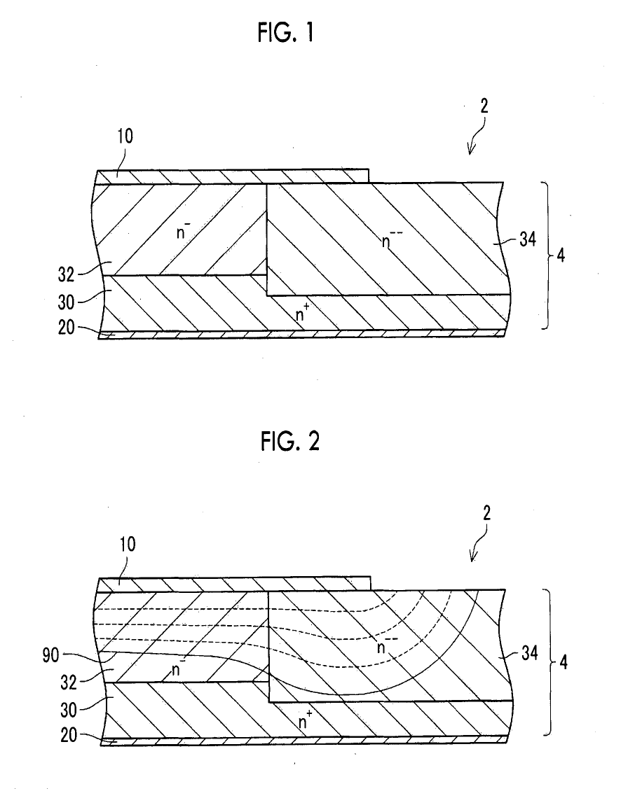

As shown in FIG. 1, an SBD 2 of this embodiment has a semiconductor substrate 4, a top surface electrode 10, and a bottom surface electrode 20.

The semiconductor substrate 4 is an n-type semiconductor substrate that is formed of Ga₂O₃. The semiconductor substrate 4 has a high-concentration layer 30, an intermediate-concentration layer 32, and a low-concentration layer 34. The high-concentration layer 30, the intermediate-concentration layer 32 and the low-concentration layer 34 are all n-type semiconductor layers. In a modification, the low-concentration layer 34 may be an i-type semiconductor layer.

The high-concentration layer 30 is formed in an area that is exposed on the entire bottom surface of the semiconductor substrate 4. The intermediate-concentration layer 32 is formed on a part of the high-concentration layer 30. The intermediate-concentration layer 32 has a top surface that is exposed on a top surface of the semiconductor substrate 4. The intermediate-concentration layer 32 has an n-type impurity concentration that is lower than that of the high-concentration layer 30. The term “impurity concentration” used herein refers to an average impurity concentration in the layer in question. The intermediate-concentration layer 32 functions as a drift layer of the SBD 2. The low-concentration layer 34 is formed in an area that surrounds the intermediate-concentration layer 32 on the high-concentration layer 30. The low-concentration layer 34 extends to a lateral side of the semiconductor substrate 4 (not shown). The low-concentration layer 34 also has a top surface that is exposed on a top surface of the semiconductor substrate 4. The low-concentration layer 34 has an n-type impurity concentration that is lower than that of the intermediate-concentration layer 32. The intermediate-concentration layer 32 has a dielectric constant that is lower than that of the low-concentration layer 34.

The top surface electrode 10 is formed in contact with a part of the top surface of the semiconductor substrate 4. The top surface electrode 10 is in Schottky contact with the top surface of the intermediate-concentration layer 32. However, the contact region between the top surface electrode 10 and the semiconductor substrate 4 extends onto the low-concentration layer 34 beyond the intermediate-concentration layer 32. The top surface electrode 10 functions as an anode electrode of the SBD 2.

The bottom surface electrode 20 is formed in contact with a bottom surface of the semiconductor substrate 4. The bottom surface electrode 20 is in ohmic contact with the bottom surface of the high-concentration layer 30. The bottom surface electrode 20 functions as a cathode electrode of the SBD 2. In this embodiment, the bottom surface electrode 20 is formed on the entire bottom surface of the semiconductor substrate 4. In a modification, the bottom surface electrode 20 may be in contact with a part of the bottom surface of the semiconductor substrate 4.

The behaviors of the SBD 2 of this embodiment are next described. When a voltage by which the top surface electrode 10 is made positive (in other words, a forward bias) is applied between the top surface electrode 10 and the bottom surface electrode 20, electrons migrate from the semiconductor substrate 4 side toward the top surface electrode 10. This causes a current to flow from the top surface electrode 10 to the bottom surface electrode 20.

When a voltage by which the bottom surface electrode 20 is made positive (in other words, a reverse bias) is applied between the top surface electrode 10 and the bottom surface electrode 20, a depletion layer 90 that extends from a Schottky interface (in other words, the interface between the top surface electrode 10 and the intermediate-concentration layer 32) into the semiconductor substrate 4 is formed as shown in FIG. 2. The depletion layer 90 is formed in the intermediate-concentration layer 32 and in the low-concentration layer 34 but does not extend into the high-concentration layer 30 with a high n-type impurity concentration. In addition, because the low-concentration layer 34 has a lower n-type impurity concentration than the intermediate-concentration layer 32, the depletion layer 90 extends more easily in the low-concentration layer 34 than in the intermediate-concentration layer 32. In FIG. 2, equipotential lines that show the potential distribution in the depletion layer 90 are virtually illustrated (refer to the broken lines in the drawing). Because the dielectric constant of the low-concentration layer 34 is higher than that of the intermediate-concentration layer 32, the intervals between the equipotential lines in the low-concentration layer 34 are relatively larger than those in the intermediate-concentration layer 32 as shown in FIG. 2. In addition, the low-concentration layer 34 is formed in an area that surrounds the intermediate-concentration layer 32 on the high-concentration layer 30 and is not separated from the high-concentration layer 30 as described above. These help to make the intervals of potential distribution (in other words, the intervals between the equipotential lines) approximately constant in the vicinity of an end of the top surface electrode 10, making the potential change in the vicinity of the end of the top surface electrode 10 less irregular. Thus, concentration of electric field in the vicinity of the end of the top surface electrode 10 is sufficiently alleviated. As a result, in the SBD 2 of this embodiment, high voltage resistance can be achieved without forming a p-type semiconductor layer in the vicinity of an end of the top surface electrode 10. In addition, the structure of the SBD 2 of this embodiment that does not use a p-type semiconductor layer is especially useful in this embodiment because the semiconductor substrate 4 is formed of Ga₂O₃, which is a material on which it is difficult to form a p-type semiconductor layer.

### Second Embodiment

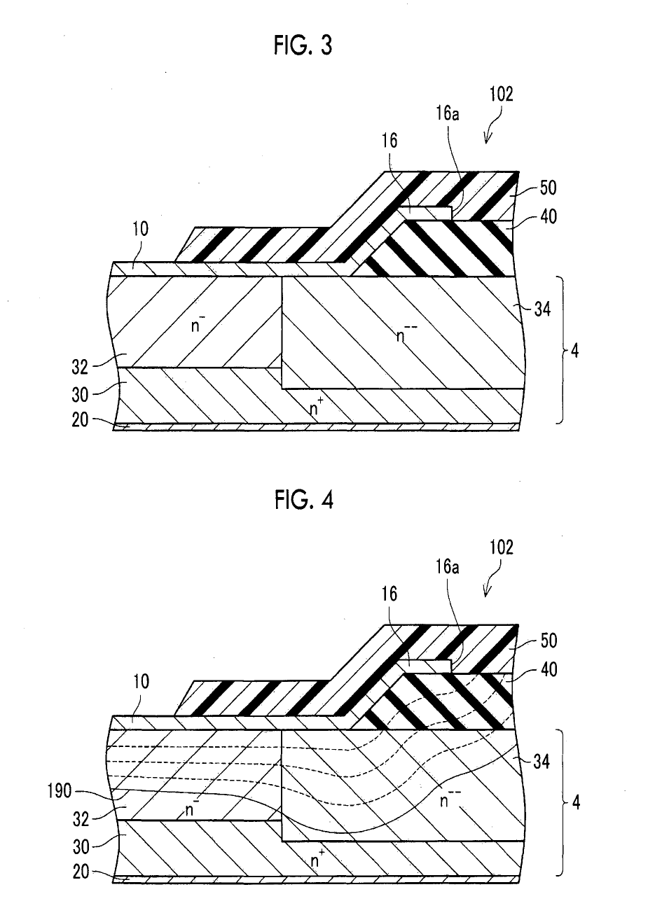

An SBD 102 of a second embodiment is next described, focusing on the differences from the first embodiment, with reference to FIG. 3 and FIG. 4. Elements similar to those of the SBD 2 of the first embodiment are designated by the same reference numerals as those used in FIG. 1 in FIG. 3 and FIG. 4, and their detailed description is omitted. The SBD 102 of this embodiment is different from the SBD 2 of the first embodiment in that it additionally includes an interlayer insulating film 40, a field plate electrode 16, and a protective film 50.

The interlayer insulating film 40 is formed in the area on the top surface of the semiconductor substrate 4 that is not in contact with the top surface electrode 10. The interlayer insulating film 40 is formed of ZrO₂. In a modification, the interlayer insulating film 40 may be formed of HfO₂. The interlayer insulating film 40 has a dielectric constant that is higher than that of SiO₂, and higher than that of the low-concentration layer 34.

The field plate electrode 16 is formed continuously from the top surface electrode 10. The field plate electrode 16 faces the low-concentration layer 34 via the interlayer insulating film 40. An end 16a (the end opposite to the top surface electrode 10) of the field plate electrode 16 is located above the low-concentration layer 34.

The protective film 50 is an insulating film that covers a part of the top surface electrode 10, the field plate electrode 16, and a part of the interlayer insulating film 40. The protective film 50 is formed of a polyimide.

The behaviors of the SBD 102 of this embodiment are next described. The behavior that takes place when a forward bias is applied to the SBD 102 is the same as that of the SBD 2 of the first embodiment and is therefore omitted from description. On the other hand, when a reverse bias is applied to the SBD 102, a depletion layer 190 that extends in the semiconductor substrate 4 and in the interlayer insulating film 40 is formed as shown in FIG. 4. In this embodiment, because the field plate electrode 16, which extends continuously from the top surface electrode 10, is provided, the depletion layer 190 extends to a position laterally away from an end of the top surface electrode 10. Thus, concentration of electric field in the vicinity of the end of the top surface electrode 10 is further alleviated. In addition, because the end 16a of the field plate electrode 16 opposite the top surface electrode 10 is located above the low-concentration layer 34, concentration of electric field in the vicinity of the end 16a of the field plate electrode 16 is also alleviated sufficiently. In addition, the dielectric constant of the interlayer insulating film 40 is higher than that of SiO₂ as described above. Thus, the intervals between the equipotential lines in the depletion layer 190 in the interlayer insulating film 40 relatively increase. This sufficiently produces the effect of alleviating concentration of electric field in the vicinity of the end of the top surface electrode 10. Thus, as described above, according to the SBD 102 of this embodiment, concentration of electric field in the vicinity of the end of the top surface electrode 10 is further alleviated and concentration of electric field in the vicinity of the end 16a of the field plate electrode 16 is sufficiently alleviated. As a result, high voltage resistance can be achieved also in the SBD 102 of this embodiment.

### Third Embodiment

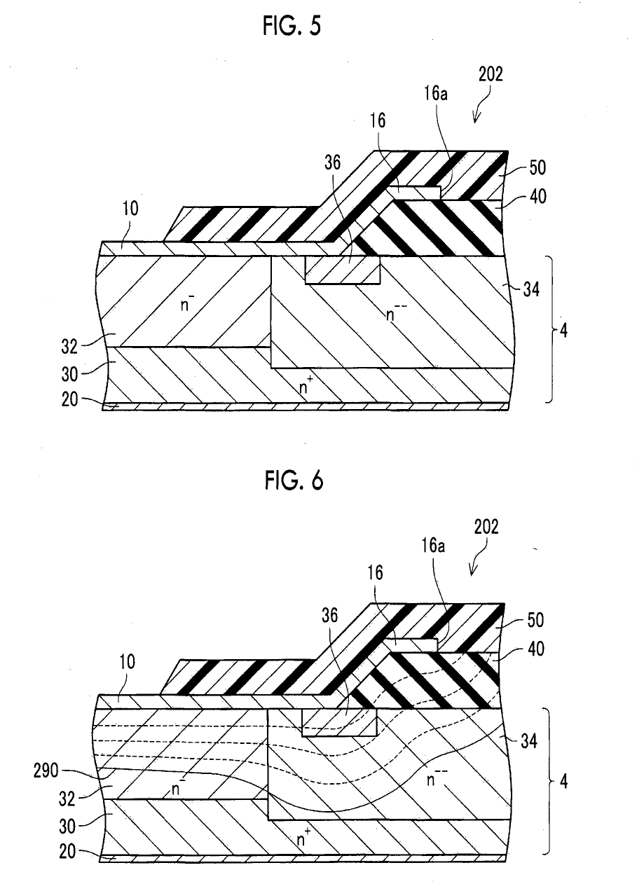

With reference to FIG. 5 and FIG. 6, an SBD 202 of a third embodiment is described, focusing on the differences from the second embodiment. Also in FIG. 5 and FIG. 6, elements similar to those of the SBDs 2 and 102 of the above embodiments are designated by the same reference numerals and their detailed description is omitted. The SBD 202 of this embodiment is different from the SBD 102 of the second embodiment in that it additionally includes an insulating layer 36 in the low-concentration layer 34.

The insulating layer 36 is formed in an area that surrounds the intermediate-concentration layer 32 in the low-concentration layer 34. The insulating layer 36 is formed by doping Fe into the low-concentration layer 34. In this embodiment, the insulating layer 36 is confined to the vicinity of the top surface of the semiconductor substrate 4 and is separated from the high-concentration layer 30. The insulating layer 36 has a dielectric constant that is higher than that of the interlayer insulating film 40. In this embodiment, an end of the contact region where the top surface electrode 10 and the semiconductor substrate 4 are in contact is located on the insulating layer 36.

The behaviors of the SBD 202 of this embodiment are next described. The behavior that takes place when a forward bias is applied to SBD 202 is again the same as that of the SBDs 2 and 102 in the above embodiments and its detailed description is therefore omitted. On the other hand, when a reverse bias is applied to the SBD 202, a depletion layer 290 that extends in the semiconductor substrate 4 and in the interlayer insulating film 40 is formed as shown in FIG. 6. In this embodiment, because the insulating layer 36 is provided in the low-concentration layer 34, concentration of electric field in the vicinity of an end of the top surface electrode 10 is further alleviated. Thus, high voltage resistance can be achieved also in the SBD 202 of this embodiment.

### Fourth Embodiment

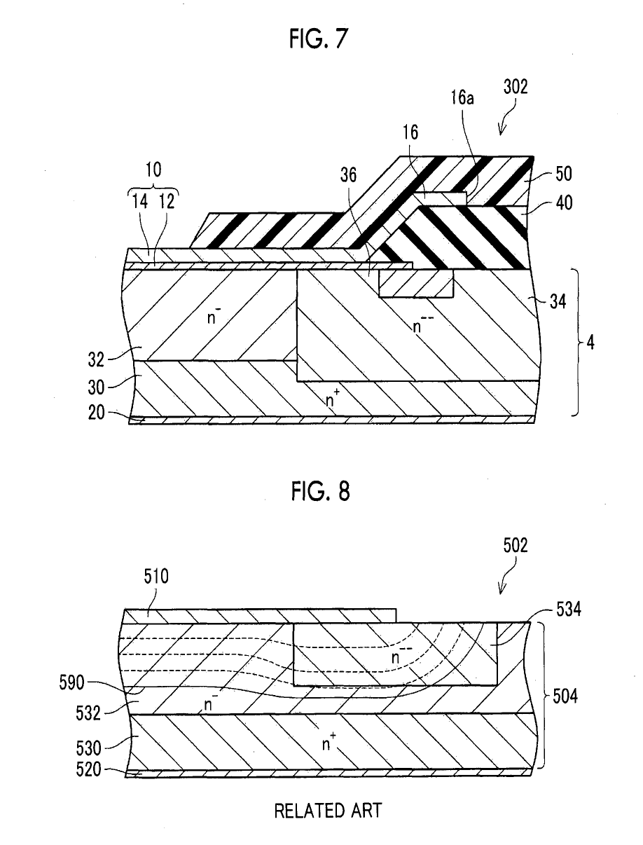

An SBD 302 of a fourth embodiment is next described, focusing on the differences from the third embodiment, with reference to FIG. 7. Again, elements similar to those of the SBDs 2, 102 and 202 of the above embodiments are designated by the same reference numerals in FIG. 7, and their detailed description is omitted. The SBD 302 of this embodiment is different from the SBD 202 of the third embodiment in that the top surface electrode 10 has a structure in which a Schottky electrode film 12 and a laminate electrode film 14 are laminated on top of each other.

As shown in FIG. 7, the Schottky electrode film 12 is in contact with a top surface of the semiconductor substrate 4. The Schottky electrode film 12 is in Schottky contact with the top surface of the intermediate-concentration layer 32. However, the contact region where the Schottky electrode film 12 and the semiconductor substrate 4 are in contact extends onto the low-concentration layer 34 beyond the intermediate-concentration layer 32. An end of the Schottky electrode film 12 is covered with the interlayer insulating film 40. The end of the interlayer insulating film 40 on the side where it covers an end of the Schottky electrode film 12 is located on the low-concentration layer 34. The laminate electrode film 14 is laminated on the part of the Schottky electrode film 12 that is not covered with the interlayer insulating film 40. The laminate electrode film 14 extends continuously from the field plate electrode 16.

The behaviors of the SBD 302 of this embodiment are almost the same as those of the SBD 202 of the third embodiment and their detailed description is therefore omitted. In the SBD 302 of this embodiment, an end of the Schottky electrode film 12 is covered with the interlayer insulating film 40 as described above. Thus, when the SBD 302 is produced, the interlayer insulating film 40 can be formed after the Schottky electrode film 12 is formed on a top surface of the semiconductor substrate 4. Thus, the Schottky electrode film 12 can be formed while the top surface of the semiconductor substrate 4 is still clean. This helps to provide a stable Schottky interface. In addition, the end of the interlayer insulating film 40 on the side where it covers an end of the Schottky electrode film 12 is located on the low-concentration layer 34, not on the intermediate-concentration layer 32, as described above. This helps to prevent an increase in conductive resistance when a forward bias is applied to the SBD 302.

While specific examples of the arts that are disclosed in this specification are described in detail in the foregoing, these are merely examples and are not intended to limit the scope of the claims. The arts that are described in the claims include various modifications and variations of the specific examples exemplified in the above embodiments. For example, any of the following modifications may be employed.

(Modification 1)

The top surface electrode 10 in the above first to third embodiments may also have a Schottky electrode film that is in contact with a top surface of the semiconductor substrate 4 and a laminate electrode film that is laminated on a top surface of the Schottky electrode film as in the fourth embodiment. In this case, the field plate electrode 16 may have a first film that extends continuously from the Schottky electrode film and a second film that extends continuously from the laminate electrode film and is laminated on a top surface of the first film.

(Modification 2)

The semiconductor substrate 4 may be formed of a material other than Ga₂O₃ such as GaN, Si or SiC. In particular, in a modification where the semiconductor substrate 4 is formed of Si or SiC, a thermally oxidized film may be additionally formed between the interlayer insulating film 40 and the low-concentration layer 34 in the second to fourth embodiments. However, when the semiconductor substrate 4 is formed of GaN or Ga₂O₃, which is a material on which it is difficult to form a p-type semiconductor layer, the structure constructed without using a p-type semiconductor layer disclosed in this specification is especially useful.

(Modification 3)

The low-concentration layer 34 may not extend to a lateral side of the semiconductor substrate 4. Generally speaking, the low-concentration layer 34 only has to be formed in an area that surrounds the intermediate-concentration layer 32 on the high-concentration layer 30, and the contact region between the top surface electrode 10 and the semiconductor substrate 4 only has to extend onto the low-concentration layer 34 beyond the intermediate-concentration layer 32.

In this specification, the expression “the n-type low-concentration layer surrounds the intermediate-concentration layer” means that the entire outer periphery of the intermediate-concentration layer is formed inside the low-concentration layer when the semiconductor substrate is viewed in a plan view.

The technology components that are shown in this specification or the drawings appended hereto achieve their technical utility on their own or in various combinations and should not be limited to the combinations that are set forth in the claims at the time of the filing of this application. Further, the technology that is described in this specification or the drawings appended hereto achieves a plurality of objects at the same time, and has technical utility even if it achieves one of the objects.

1-5. (canceled)

6. A diode comprising:
a semiconductor substrate;
a top surface electrode in contact with a part of the top surface of the semiconductor substrate;
a bottom surface electrode in contact with at least a part of the bottom surface of the semiconductor substrate; and
an insulating layer, wherein
the semiconductor substrate includes:
an n-type high-concentration layer in ohmic contact with the bottom surface electrode;
an n-type intermediate-concentration layer on a part of the n-type high-concentration layer, the n-type intermediate-concentration layer having a lower n-type impurity concentration than the n-type high-concentration layer; and
an n-type low-concentration layer on a part of the n-type high-concentration layer, the n-type low-concentration layer surrounding the n-type intermediate-concentration layer when the semiconductor substrate is viewed in a plan view, the n-type low-concentration layer having a lower n-type impurity concentration than the n-type intermediate-concentration layer, the top surface electrode is in Schottky contact with a top surface of the n-type intermediate-concentration layer, and a contact region where the top surface electrode and the semiconductor substrate are in contact extends onto the n-type low-concentration layer beyond the n-type intermediate-concentration layer,
the insulating layer surrounds the n-type intermediate-concentration layer in the n-type low-concentration layer when the semiconductor substrate is viewed in the plan view, and
an end of the contact region is located on the insulating layer.

7. The diode according to claim 6, further comprising
a field plate electrode facing the n-type low-concentration layer via an interlayer insulating film, the field plate electrode being connected to the top surface electrode, wherein
an end of the field plate electrode, the end being on an opposite side of the field plate electrode from the top surface electrode, is located in a direction to the top surface of the semiconductor substrate from the n-type low-concentration layer.

8. The diode according to claim 7, wherein
the interlayer insulating film has a dielectric constant, the dielectric constant of the interlayer insulating film being higher than a dielectric constant of the n-type low-concentration layer.

9. The diode according to claim 7, wherein
the interlayer insulating film has a dielectric constant, the dielectric constant of the interlayer insulating film being higher than a dielectric constant of SiO₂.
